(19) United States
(12) Patent Application Publication
(10) Pub. No.: US 2025/0233049 A1
(43) Pub. Date: Jul. 17, 2025

(54) MULTI-SCALE ELECTROPLATED POROUS COATING FOR IMMERSION COOLING OF ELECTRONICS

(71) Applicants: Systemex Énergies Inc., Laval (CA); East West Manufacturing, LLC, Atlanta, GA (US); SOCPRA Sciences et Génie s.e.c., Sherbrooke (CA)

(72) Inventors: Julien Sylvestre, Sherbrooke (CA); Omidreza Ghaffari, Sherbrooke (CA); Chady Al Sayed, Dollard-des-Ormeaux (CA); Seyedyaser Nabavilarimi, Sherbrooke (CA); Francis Grenier, Laval (CA); Simon Jasmin, Montreal (CA)

(73) Assignees: Systemex Énergies Inc., Laval, QC (CA); East West Manufacturing, LLC, Atlanta, GA (US); SOCPRA Sciences et Génie s.e.c., Sherbrooke, QC (CA)

(21) Appl. No.: 18/865,596

(22) PCT Filed: May 12, 2023
(86) PCT No.: PCT/CA2023/050659

§ 371 Date: Nov. 13, 2024

Related U.S. Application Data
(60) Provisional application No. 63/341,732, filed on May 13, 2022.

(51) Int. Cl. H01L 23/44; C25D 7/12; C25D 15/00; H01L 21/56; H01L 23/29

(52) U.S. Cl. CPC H01L 23/44; C25D 7/12; C25D 15/00; H01L 21/56; H01L 23/29

(57) ABSTRACT

Traditional air cooled fin heat sinks, which contain heat pipes, are generally able to evacuate the heat adequately from electronic devices at low power. However, some restrictions like a high thermal resistance at high powers and an early dry-out limit their usage in new generations of CPU and GPU. The present disclosure relates to a porous coating capable of increasing the thermal performance of data processors. The coating can be applied to after-market off-the-shelf processors and increase the thermal performance in pool boiling applications. The coating can be a multi-scale electroplated porous (MuSEP) coating that increases boiling efficiency.

### CROSS-REFERENCE TO RELATED APPLICATION

The present application claims the benefit of U.S. provisional patent application Ser. No. 63/341,732 filed on May 13, 2022. The contents of the above-referenced document are incorporated herein by reference in their entirety.

### TECHNICAL FIELD

The present disclosure relates to a cooling arrangements of electronic components, in particular to a porous coating for immersion cooling of electronics, such as a CPU, GPU or similar and also to a method for manufacturing the porous coating.

### BACKGROUND

For decades, traditional air cooled fin heat sinks, that contain heat pipes, were able to evacuate the heat adequately from electronic devices [1]. The efficiency of these kinds of heat sinks is acceptable at low power. However, some restrictions like a high thermal resistance at high powers and an early dry-out limit their usage in new generations of CPU and GPU [2]. The dry-out can lead to a die temperature that is above the max operating limit [3]. For instance, K. Baraya et al. [2] reported that dry-out could occur at 10 W/cm² in an ordinary heat pipe. Powerful CPUs require a system with a much larger heat evacuation capacity. Some manufacturers have released CPUs with approximately 400 W thermal design power (TDP), such as the Intel® Xeon® Platinum 9282, with a maximum heat flux of 27 W/cm² at the integrated heat spreader (IHS), which is much higher than the capacity of heat pipes [2]. New cooling technologies are necessary for high-power processors.

Pool boiling can be a viable candidate for this purpose, and several studies have been conducted to implement this technology for cooling applications [4]-[6]. As reported in previous work [7], an average critical heat flux (CHF) of only 8.6 W/cm² on a 1 mm thick copper IHS coated with nickel could be achieved by pool boiling, far below the heat flux of powerful contemporary CPUs.

There remains a need for new cooling technologies for high-power processors.

### SUMMARY

This Summary is provided to introduce a selection of concepts in a simplified form that are further described below in the Detailed Description. This Summary is not intended to identify key aspects or essential aspects of the claimed subject matter.

As embodied and broadly described herein, the disclosure relates to a coating for use on a heat transport surface of a data processor, the coating comprising a plurality of metal-based grains defining pores, wherein the pores form more than 35% of void area, and wherein the coating is configured for immersion cooling of the data processor.

In some embodiments, the coating may have one or more of the following features:
the pores define a pore-size gradient along at least one dimension of the coating.
the pore-size gradient extends along a thickness of the coating.
the pore-size gradient includes increasingly larger pores in a direction of heat transport through the coating.
the pores form more than 40% of void area, preferably more than 50% of void area, more preferably more than 60% of void area.
the pores at a top surface of the coating have an average pore size of at least 100 microns, preferably of at least 150 microns, more preferably at least 200 microns.
the plurality of grains form dendrite-like structures extending outwardly from a low surface thereof.
the plurality of grains includes grains having a size of about 70 microns or more at a top surface thereof, preferably from about 70 microns to about 500 microns.
the plurality of grains includes a plurality of first grains of first average size and a plurality of second grains of second average size above the plurality of grains of first average size, the second average size being larger than the first average size.
the pores include a first plurality of pores having a concave shape and a second plurality of pores having a convex shape.

As embodied and broadly described herein, the disclosure relates to a coating for use on a heat transport surface of a data processor, the coating comprising a plurality of first grains of first average size and a plurality of second grains of second average size above the plurality of grains of first average size, the second average size being larger than the first average size, the plurality of grains of first average size defining pores configured to induce bubble nucleation, and the plurality of grains of second average size defining a liquid wicking structure to draw cooling liquid toward the pores, wherein the coating is configured for immersion cooling of the data processor.

As embodied and broadly described herein, the disclosure relates to a data processor comprising: a) an integrated heat spreader having an outer surface, and b) a coating deposited on the outer surface, the coating including a plurality of grains of increasing size in a direction of heat transport through the coating, the coating configured to induce bubble nucleation during immersion cooling of the data processor during which the coating is in direct contact with a cooling liquid.

As embodied and broadly described herein, the disclosure relates to a data processor comprising: a) a semiconductor die on which a functional integrated semiconductor circuit is fabricated, the die having a surface and b) a porous coating deposited on the die for immersion cooling of the data processor.

In some embodiments, the data processor may have one or more of the following features:
the coating defines a physical protective layer for the semiconductor die.
the coating is bonded to the surface of the die through an intermediate layer.
the intermediate layer includes material configured to establish a bond with the material of the semiconductor die and the material of the coating.
the intermediate layer is a first intermediate layer, the data processor including a second intermediate layer between the first intermediate layer and the coating.
the coating includes a plurality of metal-based grains.
the plurality of metal-based grains include copper.

As embodied and broadly described herein, the disclosure relates to a process for manufacturing a coating for immersion cooling of a data processor, comprising: a) contacting a heat transport surface of the data processor with a composition including a metallic material, and b) electroplating the composition to obtain the coating on the heat transport surface of the data processor, the electroplating comprising controlling current density and plating duration to obtain a plurality of metal-based grains defining pores, wherein the pores form more than 35% of void area of the coating.

In some embodiments, the process is performed at room temperature.

All features of exemplary embodiments which are described in this disclosure and are not mutually exclusive can be combined with one another. Elements of one embodiment can be utilized in the other embodiments without further mention. Other aspects and features of the present invention will become apparent to those ordinarily skilled in the art upon review of the following description of specific embodiments in conjunction with the accompanying Figures.

### BRIEF DESCRIPTION OF THE DRAWINGS

A detailed description of specific exemplary embodiments is provided herein below with reference to the accompanying drawings in which:

FIG. 1 is a schematic illustration of a test boiling setup, in accordance with an embodiment of the present disclosure.

FIG. 2 is a schematic illustration of the heater assembly with the side view of the MuSEP coating according to an example of implementation of the disclosure. T_{C} is the case temperature and T_{H} is the heater temperature, in accordance with an embodiment of the present disclosure.

FIG. 3 shows SEM images of a) BEC™, c) MuSEP coating, and image analysis of b) porosity of the BEC™, d) porosity of the MuSEP coating, in accordance with an embodiment of the present disclosure.

FIG. 4 shows boiling curves the different three heat spreaders tested with the setup of FIG. 1, in accordance with an embodiment of the present disclosure.

FIG. 5 are curves showing the average heat transfer coefficient for the three heat spreader surfaces at different power levels, in accordance with an embodiment of the present disclosure.

FIG. 6 is a curve showing the surface-to-liquid thermal resistance of the three heat spreader surfaces at different power levels, in accordance with an embodiment of the present disclosure.

FIG. 7 is an illustration of a reliability setups of a) 4U heat sink system at 3IT, b) total immersion system, in accordance with an embodiment of the present disclosure.

FIG. 8 illustrate steps of the processor surface preparation for the deposition of the MuSEP coating, specifically FIG. 8(A) shows an Intel Xeon E5-2690 processor having nickel coated IHS with venting hole (not all CPUs have this hole on their IHS); FIG. 8(B) shows the hole being closed with silicon glue and the surface of the heat spreader polished with 200 grit paper; FIG. 8(c) shows a square shape wire to be used for uniform electrical current spreading during the deposition of the MuSEP coating, in accordance with an embodiment of the present disclosure.

FIG. 9 illustrates the preparation of the processor for the deposition of the MuSEP coating, specifically FIG. 9(1) shows a thick layer of tissues; FIG. 9(2) shows the placement of a Wide Kapton tape to cover the bottom of processor; FIG. 9(3) shows the processor placed on Kapton tape; FIG. 9(4) shows the square shaped wire fitted around the HIS of the processor; FIG. 9(4) shows the Kapton tape placed on top of the processor; FIG. 9(5) shows the extra part of the processor cut; FIG. 9(6) shows the Kapton tape cut to expose the surface of the HIS and FIG. 9(7) shows the processor after the deposition of the MuSEP coating, in accordance with an embodiment of the present disclosure.

FIG. 10 is an SEM image from the top of the coating after a second stage of the coating process, in accordance with an embodiment of the present disclosure.

FIG. 11 is an SEM image from the side after the second stage of the coating process, in accordance with an embodiment of the present disclosure.

FIG. 12 is an SEM image from the top of the coating after a third stage of the coating process, in accordance with an embodiment of the present disclosure.

FIG. 13 is an SEM image from the side after the third stage of the coating process, in accordance with an embodiment of the present disclosure.

FIG. 14 is an SEM image from the side after completion of a fourth stage of the coating process, in accordance with an embodiment of the present disclosure.

FIG. 15 is an SEM image from the top after completion of the fourth stage of the coating process, in accordance with an embodiment of the present disclosure.

FIG. 16a illustrates an experimental process for removing the integrated heat spreader (IHS) gasket, in accordance with an embodiment of the present disclosure.

FIG. 16b illustrates a package holder kit for holding the processor while the IHS is being separated from the die, in accordance with an embodiment of the present disclosure.

FIG. 16c illustrates the package placed in an oven to melt the indium bonding layer holding the IHS to the semiconductor die, in accordance with an embodiment of the present disclosure.

FIG. 16d illustrates the processor with the IHS removed, showing the indium residue on the surface of the die, in accordance with an embodiment of the present disclosure.

FIG. 16e show the die after polishing, in accordance with an embodiment of the present disclosure.

FIG. 16f shows the PCB covered with protective layer before electroplating, in accordance with an embodiment of the present disclosure.

FIG. 16g shows the PCB after the deposition of a first intermediate bonding layer by evaporation, in accordance with an embodiment of the present disclosure.

FIG. 16h shows the PCB after the deposition of a second intermediate bonding layer over the first bonding layer, in accordance with an embodiment of the present disclosure.

FIG. 16i shows the deposition of the MuSEP coating on the second intermediate bonding layer, in accordance with an embodiment of the present disclosure.

FIG. 17a, b, are illustrations of a cooling setup prototype for used in a comparative test, in accordance with an embodiment of the present disclosure.

FIG. 18a is a graph showing the junction temperature with relation to power, for different cooling scenarios, in accordance with embodiments of the present disclosure.

FIG. 18b is a graph showing the thermal resistance with relation to power for different cooling scenarios, in accordance with embodiments of the present disclosure.

FIG. 19 shows SEM images from the side of two different cross-sections of the MuSEP coating with the binary color map of the top and bottom layer for measuring the porosity of the coating, in accordance with an embodiment of the present disclosure.

FIG. 20a shows an SEM image of a MuSEP coating in accordance with an embodiment of the present disclosure.

FIG. 20b shows an SEM image of a comparative commercially available Microporous Metallic Boiling Enhancement Coating (BEC) from 3M™.

In the drawings, exemplary embodiments are illustrated by way of example. It is to be expressly understood that the description and drawings are only for the purpose of illustrating certain embodiments and are an aid for understanding. They are not intended to be a definition of the limits of the invention.

### DETAILED DESCRIPTION

The present technology is explained in greater detail below. This description is not intended to be a detailed catalog of all the different ways in which the technology may be implemented, or all the features that may be added to the instant technology. For example, features illustrated with respect to one embodiment may be incorporated into other embodiments, and features illustrated with respect to a particular embodiment may be deleted from that embodiment. In addition, numerous variations and additions to the various embodiments suggested herein will be apparent to those skilled in the art considering the instant disclosure which variations and additions do not depart from the present technology. Hence, the following description is intended to illustrate some embodiments of the technology, and not to exhaustively specify all permutations, combinations, and variations thereof.

The present inventors have through R&D work surprisingly and unexpectedly designed and developed an improved coating for use on a heat transport surface of a data processor, which is capable of increasing the thermal performance of the data processor.

In one broad aspect, the present inventors have designed and developed a coating for use on a heat transport surface of a data processor, where the coating comprises a plurality of metal-based grains defining pores, where the pores form more than 35% of void area, and where the coating is configured for immersion cooling of the data processor.

In a non-limiting implementation, the coating is a multi-scale electroplated porous (MuSEP) coating, which is capable of increasing boiling efficiency.

In some embodiments, the desired coating may be characterized as comprising a plurality of metal-based grains defining pores, where the pores form more than 35% of void area. In some embodiments, the desired coating may be further characterized as having a pore-size gradient along at least one dimension of the coating. In some embodiments, the pore-size gradient may include increasingly larger pores in a direction of heat transport through the coating. In some embodiments, the desired coating may be further characterized as comprising a plurality of first grains of first average size and a plurality of second grains of second average size above the plurality of grains of first average size, the second average size being larger than the first average size, the plurality of grains of first average size defining pores configured to induce bubble nucleation, and the plurality of grains of second average size defining a liquid wicking structure to draw cooling liquid toward the pores. In such embodiments, the pores may include a first plurality of pores having a concave shape and a second plurality of pores having a convex shape. In some embodiments, the coating includes a transition portion including a mixture of concave shape pores and convex shape pores. For example, the transition portion may be included between a first portion including substantially concave shape pores and a second portion including substantially convex shape pores. For example the first portion including substantially concave shape pores may be located at a top layer of the coating and the second portion including substantially convex shape pores may be located at a bottom layer of the coating.

In one broad aspect, the present inventors have designed and developed a process for manufacturing the coating for immersion cooling of a data processor. The process comprises contacting a heat transport surface of the data processor with a composition including a metallic material, and electroplating the composition to obtain the coating on the heat transport surface of the data processor, the electroplating comprising controlling current density and plating duration to obtain a plurality of metal-based grains defining pores, where the pores form more than 35% of void area of the coating.

In some embodiments, the process includes depositing the porous coating to the heat transport surface of the data processor at a temperature that does not damage the data processor. For example, at ambient temperature (e.g., a temperature between about 22° C. and about 28° C.).

The process described herein can be implemented on off-the-shelf data processors, such as central processing units (CPUs) and graphics processing units (GPUs).

Moreover, such process may afford one or more advantages over alternate coating procedures, such as particle sintering, that require a high temperature environment or create high mechanical stresses might not be practical due to the reliability issues. Electroplating is a process that could be carried out at room temperature and is viable for coating. The electroplating can be performed on off-the-shelf consumer-grade processors [11]. Using the electroplating method for coating has some advantages such as low processing cost, low operating temperature, a simple coating setup, and high boiling performance.

In a specific example of implementation, the coating process is performed at room temperature and could be applied on any heat surface of the data processor, such as the integrated heat spreader (IHS) or the semiconductor die on which the functional semiconductor is made. Boiling directly on the dies of multi-die chips is also financially effective, considering the costly processes of the chips surfaces alignment and challenges of brazing the IHS on the chips. The two curves of boiling on the coated die and boiling on the coated IHS crossed each other at (80±6.4) W which indicates the benefit of heat spreading at high powers, while at low powers, a coated die showed immediate responses and the outcome was a lower junction temperature. The promising cooling results of the coating described herein on die demonstrates the potential in application of this new technology in cooling of the Modular chiplets configured processors.

Without being bound by any theory, it is believed that the herein described porous coating and method of obtaining same affords one or more advantages such as increasing the heat transfer coefficient (HTC), promoting the boiling incipience, and delaying the critical heat flux (CHF). For example, to increase the HTC, the number of nucleation sites have been increased compared to commercially available porous coatings. For example, the wicking behavior of the surface should be improved to delay the CHF. Promoting boiling incipience helps lower the thermal resistance at low power. On a bare copper surfaces, the nucleation starts at 13° C. surface superheat (Tₛ−Tₗ) [7]. Reducing this surface superheat would allow the processor to work at a lower temperature. A porous coating could initiate boiling at lower surface superheat. In addition, the porous coating could increase the boiling heat transfer coefficient and delay the critical heat flux (CHF) [8]-[11]. The porous structure directly impacts the phenomena involved in the pool boiling.

The coating porosity and thickness are two important characteristics of the structure that affect the boiling. Furthermore, wettability plays a vital role in heat transfer. Using a liquid with lower surface tension that boils on a wettable surface (low contact angle) results in a high capillary force. A higher capillary force helps the liquid pass through the porous structure faster and prevents surface dry-out. A porous coating provides more wicking paths for the liquid [12], [13].

### A. TEST BENCH

Boiling tests were performed in a chamber at atmospheric pressure. The chamber (diameter: 30 cm; height: 24 cm) was partially filled with Novec™649, so the free surface of the liquid was 10 cm higher than the boiling surface, for a filling ratio of 60%. The physical properties of the Novec™649 fluid are presented in table 1.

TABLE I
Physical Properties of Novec ™649 [19]

| Novec ™649 | Values |
|---|---|
| Boiling Point (° C.) | 49 |
| Heat of Vaporization (kJ/kg) | 88 |
| Liquid Density (kg/m³) | 1600 |
| Specific Heat (J/kg · K) | 1103 |
| Thermal Conductivity (W/m-K) | 0.059 |
| Surface Tension (mN/m) | 10.8 |
| Dielectric Constant at 1 kHz | 1.8 |
| Vapor density (Ref Std air = 1) | 11.6 |
| Vapor pressure (kPa) | 40 |
| Kinematic viscosity (cSt) | 0.4 |

The condensation section is mounted at the top of the chamber and comprises an aluminum pin array heat sink connected to a cold plate (Lytron, CP15G01), with the pins placed downward. The condenser is over-designed and could remove heat loads up to 1000 W, while the maximum power achievable from the heater is 490 W. The heater assembly at the bottom comprises a ceramic heater (Watlow, CER-1-01), Teflon housing, copper block for conducting the heat from the heater to the boiling surface, and a spring to press the heater at the copper block to provide proper contact. The Teflon housing functions as a holder for the heater, also as an insulator to minimize the lateral heat loss and direct most of the heat upward. The top surface of the copper block is inside the tank, and the three types of heat spreaders were attached to it. A thermal interface material (Arctic, MX-4, 8.5 W/m·K) is used to make an efficient contact between the copper block, the heat spreader and the heater.

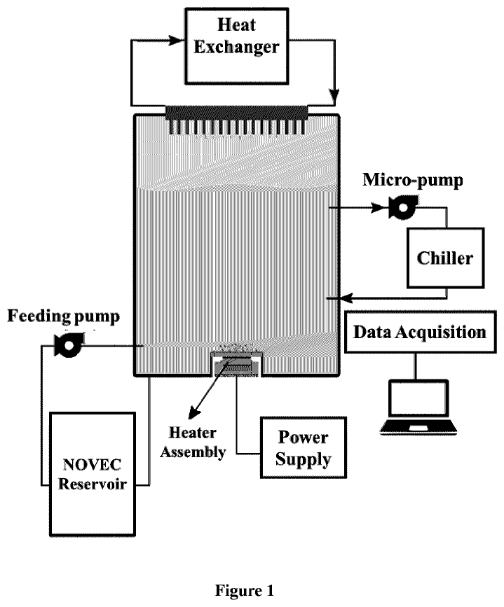

The pressure and the temperature are monitored during the experiments. Therefore, the chamber is equipped with K-type thermocouples (Omega, M12KIN) and one pressure gauge (OMEGA, PX409). The thermocouples measure the liquid temperature (Tₗ), IHS surface temperature (Tₛ), and the heater temperature. The setup is designed to imitate a functioning commercial processor like a CPU or a GPU. Therefore, one of the thermocouples is placed 1 mm below the top surface of the copper block and is used to read the surface temperature. The pressure sensor is placed at the top of the tank to monitor the system internal pressure. The chamber is equipped with a valve on the top, which is open during all experiments to keep the system at atmospheric pressure. To prevent excessive vapor loss from the chamber, the condenser functions at its highest capacity. The main chamber is made of stainless steel and it is covered with a 1 cm thick polyurethane foam for thermal insulation (thermal conductivity at 20° C.: 0.03 W/m·K). Three windows are placed in the front and the two sides, providing appropriate visual access to the boiling surface. A 1 kW chiller (Lytron, RC011J03) is also used to cool the water passing through the cold plate to 6° C. The system is powered by a DC power supply (Keysight, N8921A). A PXI data acquisition device (National Instruments, PXIe-1078) is used to acquire all the data. A schematic illustration of the setup is presented in FIG. 1, and more detailed of the experimental setup can be found in reference [20].

### B. HEAT SPREADER

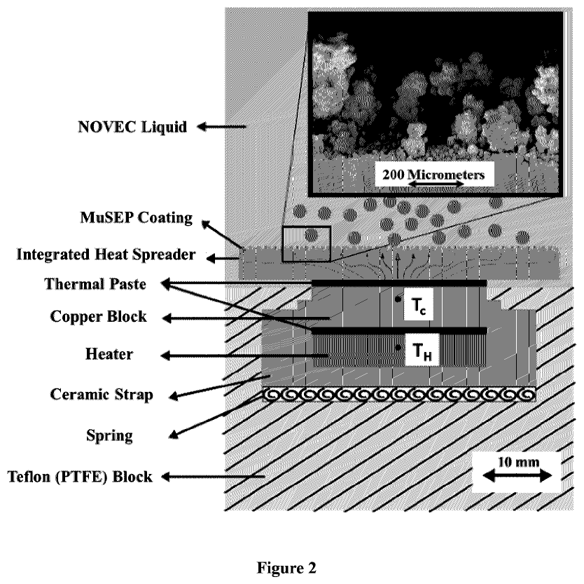

Using a heat spreader helps transfer heat from high to low heat flux media. Three square heat spreaders with dimensions of 47 mm by 47 mm were prepared, including a bare copper surface polished with 1500 grits sandpaper, a commercial Microporous Metallic Boiling Enhancement Coating (BEC™) from the 3M™ corporation, and a MuSEP coating on 4 mm thick substrates for a fair comparison. The commercial BEC™ consisted of sintered particles coated on the substrate. All the heat spreaders are positioned horizontally on the heater assembly. A schematic of the heater assembly with a side view image of the MuSEP coating is shown in FIG. 2.

### C. MULTI-SCALE ELECTROPLATED POROUS COATING (MuSEP)

In this example, the MuSEP coating is fabricated by electroplating deposition of porous copper on the copper heat spreader (the substrate). The deposition was carried out in four consecutive steps in which the current density and the duration of plating were varied. The copper and hydrogen ions undergo two reduction reaction at the surface of the substrate (cathode):

2Cu²⁺+2e⁻→Cu (1)

2H⁺2e⁻→H₂ (2)

The coating is initiated by depositing a thin layer at low current for 10 minutes. This layer provided a robust anchor to the substrate. In the second step, a high current density is applied for a few seconds to form an amorphous structure with random porosity and roughness. This step creates some active spots for growing dendrites. In the third step, the nucleated dendrites grow. In this step, the larger grains and final pores are developed and structured. A low current for four hours is applied to rigidify the grains created at the third stage. The MuSEP coating has been tested in two passive two-phase cooling systems [11], [22] and has demonstrated superior thermal performance.

### D. IMAGE ANALYSIS

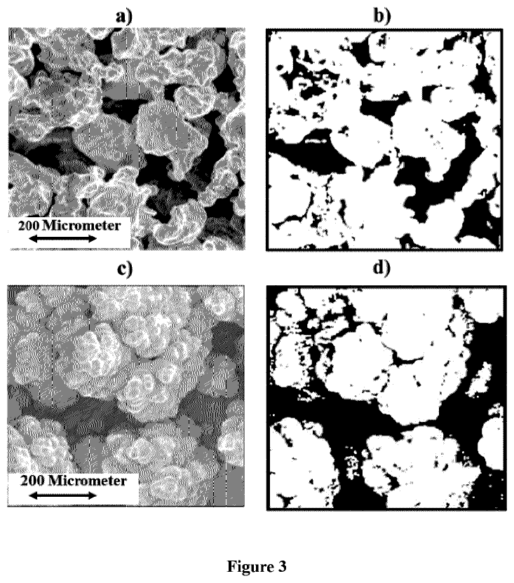

The porosity of the BEC™ and the MuSEP coating is estimated using the ImageJ software [23]. The SEM images from the top views of the MuSEP coating and the BEC™, as well as the binary results obtained from ImageJ software, are shown in FIG. 3. The binary images are generated by adjusting the color threshold using the Otsu method in the ImageJ software. The value used for the threshold of each coating is set by observing a sample visually (making sure that the borders between each pore on the surface is sharp) and making sure that the value of the calculated porosity of SEM images of the coating at difference areas of the coating surface (top, middle, bottom) was in agreement (±5%). The analysis shows that the MuSEP coating is more porous than the BEC™. For the BEC™, the porosity was estimated at 35% while the porosity of the MuSEP coating is more than 35%. The porosity of the MuSEP coating is preferably more than 40%, more preferably more than 50% and even more preferably more than 60%.

One beneficial characteristic of the MuSEP coating is the diversity of pore sizes and the existence of larger grains on the top layer (depicted in FIG. 1). The MuSEP coating delivers more larger pores than the BEC™. For example, the number of pores within the size of more than 200 microns on both coatings was measured. MuSEP coating had approximately four times more pores than that of the BEC™. Furthermore, the grain size increases along the thickness of the coating as it can be seen from FIG. 3c), smaller grains exist at the bottom of the MuSEP coating. These small grains provide smaller pores near the surface, where the bubbles are nucleated. On the other hand, larger grains at the top layer could serve as a liquid wicking structure. On the contrary, the BEC™ has a more uniform texture with smaller pores, delivering a narrower pore size distribution and lacking a proper wicking structure. The thickness of the two coatings were approximately 500 microns.

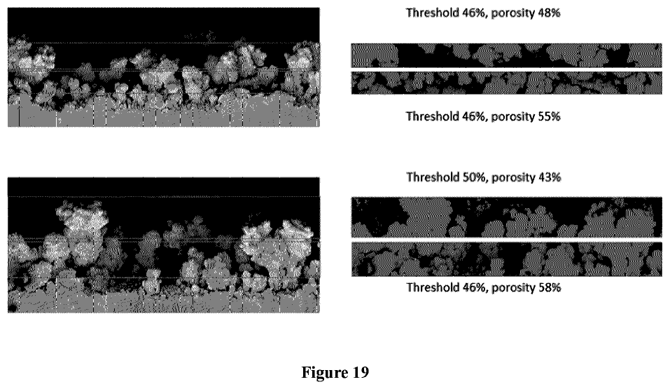

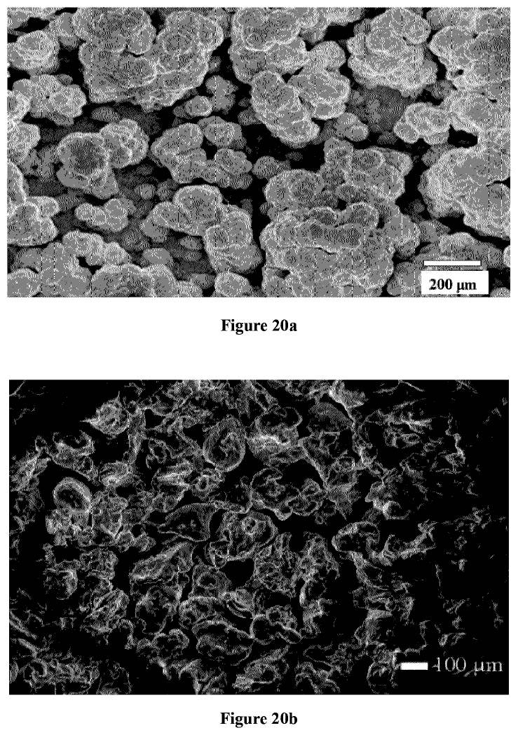

In a specific example of implementation, the porosity varies from 58% to 45% on average, along the thickness from bottom to top. At the top, the porosity is less, but the pore size is larger. The bottom layer has a higher porosity with smaller pore size. The ImageJ software was used to estimate the porosity from the cross-view images of two different sections, as shown at FIG. 19. The MuSEP coated layer was divided into two narrow sub-images at each section (representing the top layer and the bottom layer). Then, the threshold was adjusted by visually discriminating the grains and empty areas. The area fraction of the brighter regions corresponds to the porosity.

The porosity of the coating is different from the center to the side. This gradient in the porosity is more significant near the boundaries. However, it does not make any notable changes in boiling performance where there is a heat spreading since the heat flux at the boundaries is relatively low compared to the center.

When the coating according to an example of implementation of the present disclosure is compared to the commercially available BEC™ from 3M™, the following differences between the coatings are noted:

| Coating according to an | |
|---|---|
| example of implementation | |
| of the present disclosure | 3M BEC ™ |
| Can be applied at room temperature | Application performed at high temperature |
| | oven (850° C.) by sintering |
| Can be applied on CPU/GPU and | Cannot be applied on CPU and GPU or die |
| semiconductor die | as the high sintering temperature will |
| | destroy the CPU/GPU or semiconductor die |
| Bigger grain size on top | Generally uniform grain size from bottom |
| | to top |
| Larger gradient porosity from | Generally uniform porosity from bottom |
| bottom to top | to top |

thickness of the coating as it can be seen from FIG. 3c), smaller grains exist at the bottom of the MuSEP coating. These small grains provide smaller pores near the surface, where the bubbles are nucleated. On the other hand, larger grains at the top layer could serve as a liquid wicking structure. On the contrary, the BEC™ has a more uniform texture with smaller pores, delivering a narrower pore size distribution and lacking a proper wicking structure. The thickness of the two coatings were approximately 500 microns.

In a specific example of implementation, the porosity varies from 58% to 45% on average, along the thickness from bottom to top. At the top, the porosity is less, but the pore size is larger. The bottom layer has a higher porosity with smaller pore size. The ImageJ software was used to estimate the porosity from the cross-view images of two different sections, as shown at FIG. 19. The MuSEP coated layer was divided into two narrow sub-images at each section (representing the top layer and the bottom layer). Then, the threshold was adjusted by visually discriminating the grains and empty areas. The area fraction of the red regions corresponds to the porosity.

The porosity of the coating is different from the center to the side. This gradient in the porosity is more significant near the boundaries. However, it does not make any notable changes in boiling performance where there is a heat spreading since the heat flux at the boundaries is relatively low compared to the center.

When the coating according to an example of implementation of the present disclosure is compared to the commercially available BEC™ from 3M™, the following differences between the coatings are noted:

| Coating according to an example | |
|---|---|
| ofimplementation of the | |
| present disclosure | 3M BEC ™ |
| Can be applied at room temperature | Application performed at high temperature |
| | oven (850° C.) by sintering |
| Can be applied on CPU/GPU and | Cannot be applied on CPU and GPU or die as the |
| semiconductor die | high sintering temperature will destroy the |
| | CPU/GPU or semiconductor die |
| Bigger grain size on top | Generally uniform grain size from bottom to top |
| Larger gradient porosity from bottom to top | Generally uniform porosity from bottom to top |
| Pore size range - 10 micron to 300 micron | Pore size range - 10 micron to 150 micron |
| in a specific example | |
| Bigger pores prevent vapor chocking at | More chance of vapor chocking at higher power |
| higher power | due to limited pore range |
| Bigger grains on top help better wicking | |
| of liquid toward the bottom | |

### E. EXPERIMENTAL PROCEDURE

All the experiments were carried out at atmospheric pressure. Degassing the liquid prior to any test is advisable, as the presence of non-condensable gases reduces the condensation efficiency. In addition, the presence of air in the liquid may affect the bubbles nucleation. For degassing, the liquid is heated to its saturation point and is boiled for one hour. The vapor is purged every five minutes by opening the release valve.

The liquid temperature is maintained between (47±0.1)° C. and (48±0.1)° C. during all the experiments. Since the boiling incipience occurs immediately on the BEC™ and the MuSEP coating, natural convection could not be observed in the experiments. Boiling curves are generated by a gradual increase of the power, up to the power supply limit. The steady-state is considered reached when the peak-to-peak variation of temperature is less than 0.2° C. over a period of 120 s. The temperature is then obtained by averaging over a period of 30 s.

### F. UNCERTAINTIES

The uncertainties on the measurements were calculated using the combined root-sum-square method,

$$δ S = \sqrt{{\sum }_{i = 1}^{i = k} {( \frac{\partial S}{\partial {x}_{i}} δ {x}_{i} )}^{2} ,} \qquad ( 3 )$$

where δS is the standard deviation of value S, δxᵢ is the standard deviation on the ith dependant measurement and k is the number of dependent measurements. The uncertainty was given by Uₛ=2δS for a 95% confidence level (assuming Gaussian errors).

By assuming that all the electric power was converted into heat, the average heat flux (q″) on the heat spreader was calculated by multiplying the voltage (V) and the current (I) of the power supply divided by the surface area,

$${q}^{″} = \frac{VI}{WL} , \qquad ( 4 )$$

where W and L are the width and the length of the IHS, respectively. The standard deviation on the dimensions comes from the machining precision, which was δₚ=0.1 mm. The voltage and current readings from the power supply had a standard uncertainty of 2% and 1%, respectively, giving an uncertainty at maximum power of 4.5% using Equation (3).

The average heat transfer coefficient (H̅T̅C̅) was calculated by

$$\overline{HTC} = \frac{{q}^{″}}{( {T}_{s} - {T}_{l} )} . \qquad ( 5 )$$

Both thermocouples had a standard deviation of 0.1 K. The uncertainty on H̅T̅C̅ at the highest value was 12% using Equation (3).

The surface-to-liquid thermal resistance (Rₛ₋ₗ) was calculated by dividing the temperature difference (Tₛ−Tₗ) by the total power consumption,

$${R}_{s - l} = \frac{{T}_{s} - {T}_{l}}{VI} . \qquad ( 6 )$$

Using Equation (3), the uncertainty for (Rₛ₋ₗ) at the maximum power was 4.5%.

### G. BOILING CURVES

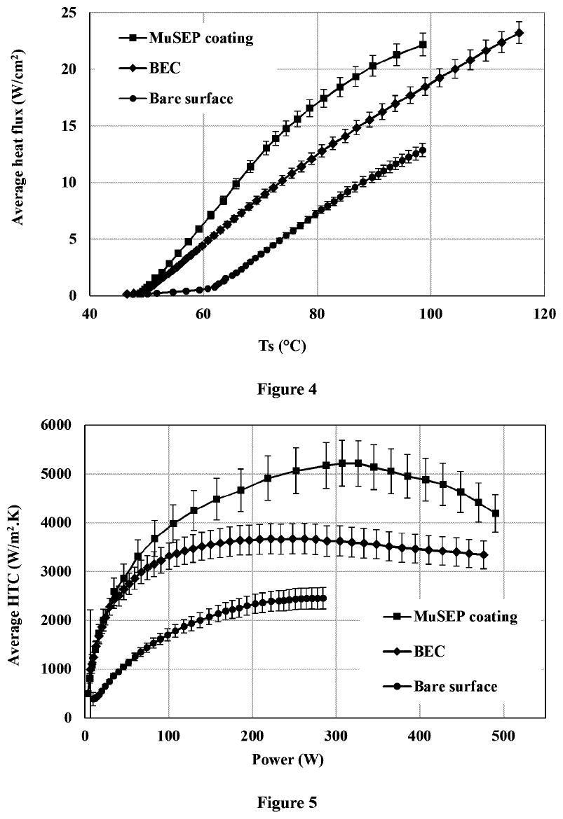

FIG. 4 shows the boiling curves generated for the three heat spreaders up to (490±22) W. For the bare surface, boiling is initiated at 13° C. surface superheat (Tₛ−Tₗ). The results for the MuSEP coating show a significant improvement in boiling performance at all ranges of power compared to the bare surface. For the porous coatings, nucleation started without delay and initiated right after the surface temperature reached the saturation temperature of the liquid.

On the bare surface, at Tₛ below 60° C., natural convection is the only heat transfer mechanism. The surface temperature increases rapidly with input power until nucleation is initiated. At the onset of boiling on the bare surface, the surface is not entirely covered by nucleation sites. A significant part of the surface remains bubble-free, and only a portion of the surface contributes to boiling. In the region of boiling initiation, a mix of boiling and natural convection is responsible for heat transfer.

The nucleation site density increases as higher power is applied until the entire surface is covered with bubbles. When the entire surface contributes to bubble formation, the pool boiling mechanism becomes the governing mode of heat transfer. Because of lateral heat spreading, the heat flux varies from the center of the surface to the sides, and only the average heat flux (q″) is considered here. The bare surface reaches the CHF at (284±13) W (q″ of 12.8±0.6 W/cm²), while the CHF is not reached for the porous surfaces up to 490 W. At a medium power like (250±11) W, which is in the range of the TDP of new powerful microprocessors, the surface temperature of the bare surface was 92° C., while it is 79° C. for the BEC™ and 68° C. for MuSEP coating. The 24° C. improvement in case temperature is very advantageous.

By comparing the BEC™ and the MuSEP coating, it can be seen that it is beneficial to have a multi-layer porous structure with multiple pore sizes and larger spaces for bubble to escape. Without intent of being bound by a specific theory, the inventors believe that at low power, tiny pores are active and deliver small bubbles. By raising the input power, the growth of the bubbles is faster and more bubbles with larger sizes depart from the surface. It is also likely that bubbles coalesce underneath the porous structure and make even larger bubbles. The larger bubbles need more space to travel upward. Therefore, larger pores provide more space at higher power levels for bubble growth and wider channels for bubbles to escape.

It can be seen from FIG. 2 the morphology of the MuSEP coating is such that it crates large void spaces between the grains at the surface of the MuSEP coating. The average dimension of those void spaces is of at least 100 microns, preferably of more than 150 microns and even more preferably of more than 200 microns. The bubbles are mostly generated in these void spaces. At high powers, bubbles grow faster, and the delay between each departure is lowered, which leads to the formation of bubble columns. It is favorable that the bubble columns do not interact to prevent merging. In addition to wicking the liquid to the boiling spots, the large grains separate the bubble columns that help delay the CHF.

### H. HTC CURVES

FIG. 5 displays the H̅T̅C̅ curves (from case to liquid) obtained for the three surface types. For the three surfaces, the H̅T̅C̅ started to increase from the beginning of boiling. The increase is more rapid in the porous surfaces as more nucleation sites become active. For the bare surface, the H̅T̅C̅ increases smoothly from low power, and the slope decreases with the increase of power. The increasing trend continues until the surface reaches the CHF. For the BEC™, a sharp increase in the H̅T̅C̅ is observed at the early stages of boiling. For the MuSEP coating, the increasing trend is even sharper, which shows the advantage of the MuSEP coating even at low power. For example, at (60±2.7) W (q″ of 2.7 W/cm²), the BEC™ shows a 128% enhancement compared to the bare surface, while the MuSEP coating improved the H̅T̅C̅ by 163%. At (250±11) W, the BEC™ has a 50% improvement in H̅T̅C̅ compared to the bare surface, while the MuSEP coating shows 108% enhancement. The increasing trend continued for the MuSEP coating until it reached its maximum H̅T̅C̅ value of (5200±470) W/K·m² at (307±14) W.

At powers above approximately 100 W, the increasing trend in H̅T̅C̅ stops for the BEC™, while for the MuSEP coating, the increasing trend continued until 300 W. This superior performance could be related to the multi-scale pore structure and the possibility of generating more nucleation sites at a higher power range. Having numerous multi-scale pore sizes allows the surface to function more efficiently over a wider heat flux range. At power levels above 100 W, the BEC™ did not show significant changes in values of the HTC, and that could be because of the uniform porosity with a small pore size range across the surface. The porosity of the BEC™ is also uniform across its thickness, while it varies from small pores at the bottom to large pores at the top for the MuSEP coating. It has been reported that a surface generating smaller bubbles at a higher frequency is more efficient for heat transfer [24]-[26].

### I. THERMAL RESISTANCE

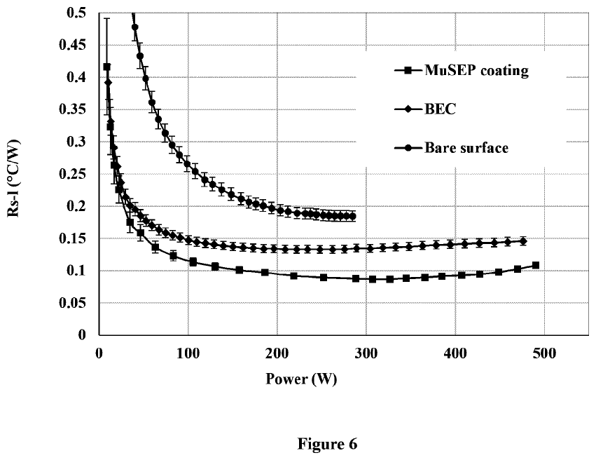

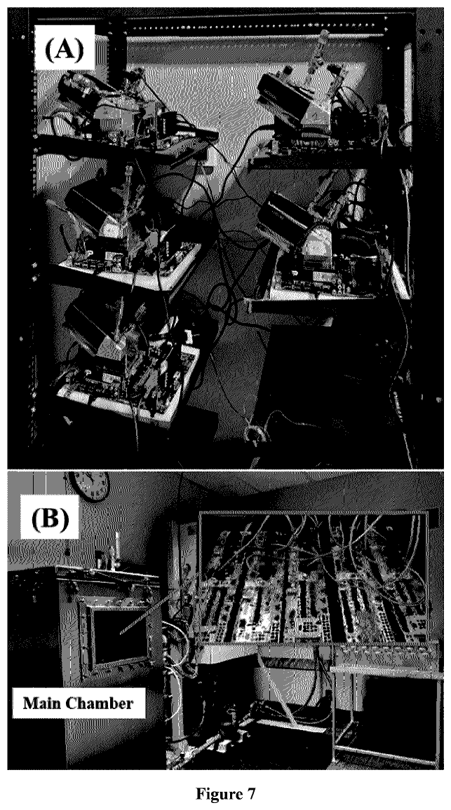

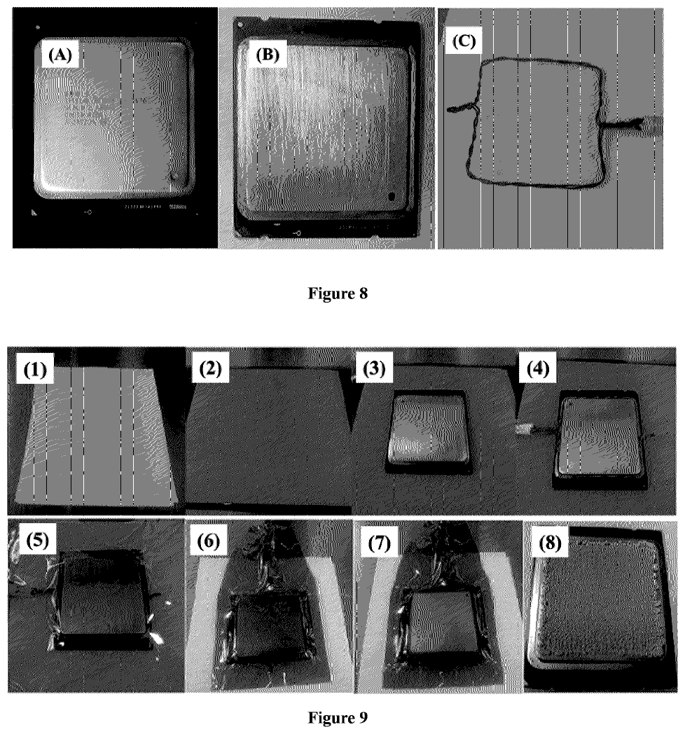

FIG. 6 shows the experimental results of Rₛ₋ₗ for the three surfaces. The results show that for the MuSEP coating, Rₛ₋ₗ is lower than the one for the BEC™ and the bare surface. The resistance Rₛ₋ₗ, for the bare surface is higher than for the two porous surfaces. The minimum thermal resistance achieved is (0.185±0.008)° C./W for the bare surface, (0.133±0.006)° C./W for the BEC™, and (0.087±0.004)° C./W for the MuSEP coating.

### J. EXAMPLE OF THE PROCESS FOR PERFORMING THE DEPOSITION OF THE MuSEP COATING

The coating is initiated by depositing a thin layer at low current for 10 minutes. This layer provides a robust anchor to the substrate. In the second step, a high current density is applied for a few seconds to form an amorphous structure with random porosity and roughness. This step creates some active spots for growing dendrites. In the third step, the nucleated dendrites are allowed to grow. In this step, the larger grains and final pores are structured. A low current for four hours is applied to rigidify the grains created at the third stage.

In the above examples, the coating, in particular the MuSEP coating is applied on the IHS. It is also possible to apply the coating directly on the semiconducting die. In this form of implementation, the MuSEP coating acts both as physical protection for the die and also as a heat dissipation layer. A specific advantage of applying the coating on the die resides in the reduction of the thermal resistance between the heat source (the die) and the heat dissipation layer.

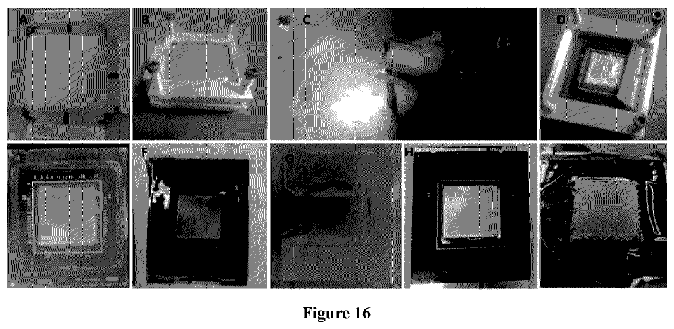

The process of the MuSEP coating on the die could be divided into three main sub-steps and it is illustrated at FIG. 16. The first step is removing the IHS to reach the silicon chip. The IHS of an Intel Xeon E5-2690 processor is attached to the PCB by a rubber gasket for sealing purposes. The gasket is removed using a sharp blade as shown at FIG. 16a. The center of the IHS is indium brazed on the silicon die. The indium is melted to allow the IHS to be separated from the die. To accomplish this, the CPU is sandwiched between two aluminum plates (holder kit), shown at FIG. 16b and placed upside-down in an oven, as shown at FIG. 16c. A thermocouple is placed inside the oven, and the tip of the thermocouple is in contact with placed on the holder kit to measure the temperature. Then, the holder kit is heated up to 170° C., allowing the IHS to drop by gravity when the indium melts. As shown at FIG. 16d, the indium residues on the die should be removed from the surface of the die before further action, and the silicon surface should be exposed. For that purpose, the bulk of the indium was removed gently using a sharp blade. Then the chip was polished using 1500 grit sandpaper. The polishing step should be done very carefully to prevent any damage or cracks on the chip. The polished die is shown at FIG. 16 e.

The second main step is coating an intermediate bonding layer, such as an intermetallic layer to have a proper binding between the MuSEP coating and the silicon chip since the copper is not adhesive to the silicon. For that purpose, the surrounding of the silicon chip is covered with Kapton tapes, as shown at FIG. 16f and only the silicon surface is exposed. Then an intermediate bonding layer of 500 nm titanium is applied via an evaporation technique, followed by the deposition of a second intermediate bonding layer of copper of a thickness of approximately 500 nm by using the same technique.

The third main step is applying the MuSEP coating on the copper layer which is generally performed according to the steps described above. All the Kapton tapes from the last step should are removed to expose the intermediate copper bonding layer and the PCB is covered again with Kapton tape. The taping should be done with care so that the electroplating solution does not leak through the other parts of the package to prevent any damage caused by wetting. The practical challenge for the electroplating step was connecting the wires to the silicon chip (cathode). One way of having the electrical current pass through the cathode surface was by connecting the wires on the exposed surface. Only the tip of the wires should be exposed to minimize the deposition on the wire since any current leaks through the wires, and other spots can cause inaccuracy in the coating.

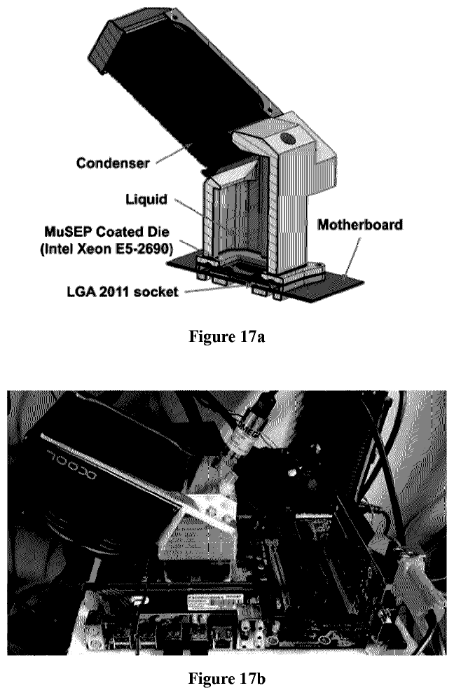

A comparison between the different coatings was made to assess their thermal diffusion performance. A traditional high-performance heat sink (Manufacturer: Deepcool) was used as the baseline for this study. The test setup is shown at FIGS. 17a and 17b. A nickel-coated IHS was used for the boiling in a second scenario where the HIS is uncoated and exposed to the boiling liquid. Then, the Multi-Scale Electroplated Porous (MuSEP) coating, was applied to the IHS of the same CPU for a third boiling scenario. Finally, the MuSEP coating was applied directly on the die in a fourth scenario of cooling. The cooling prototype was mounted on a Jinsha X79P ATX motherboard operated via Ubuntu desktop operating system. The motherboard was equipped with an Intel® Xeon® E5-2690 processor in an LGA 2011 socket. The condensation section was made of a copper radiator (Manufacturer: Alphacool International GmbH). An open-source program (stress terminal user interface (S-TUI)) was used to load a selected number of CPU threads going from 2 to 16 threads. For each test, the CPU was stressed for 15 minutes to reach the steady-state, and the temperature of the CPU was obtained by calculating the average temperature of all eight cores from the digital thermal sensors embedded in every core of the CPU. The thermal power dissipated by the CPU was estimated with the Intel Running Average Power Limit (RAPL) interface. The ambient air temperature for all tests was (21±1)° C. The uncertainties of power estimation were 8%, and thermal resistance was 10%.

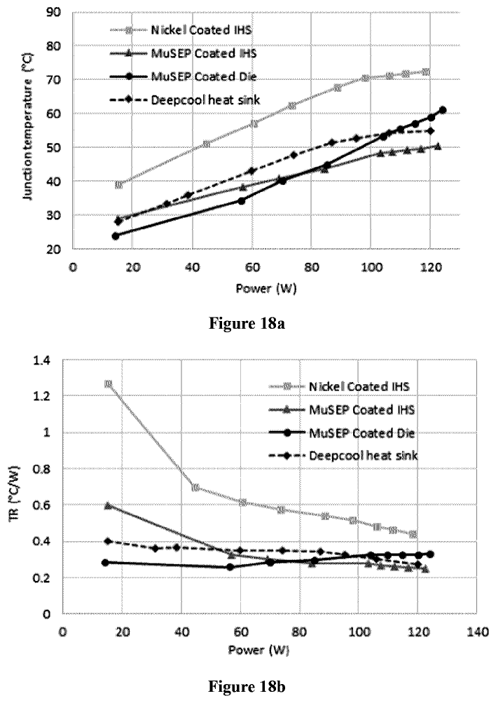

The obtained results for the three scenarios are shown in the graphs of FIGS. 18a and b. There is a significant improvement in cooling performance when the MuSEP coating is applied on the surfaces compared to boiling on the bare surface (see FIG. 18a). Boiling on the MuSEP coated surface decreases the junction temperature by 20° C. at different power levels compared to boiling on the bare surface. Comparing the two porous-coated boiling scenarios indicates that boiling directly on the die is more efficient at low powers (below 70±5.6 W). It could be seen from FIG. 18a that at powers higher than (80±6.4) W, the coated IHS has a superior performance, which emphasizes the advantages of having a heat spreader in the CPU packaging by delivering a larger surface area for the boiling.

FIG. 18b shows the three scenarios total junction-to-ambient thermal resistance (TR), including the baseline of a traditional heatsink. At the initial power, the total TR for the MuSEP coated die is lower since the TIM1 and IHS related (heat spreading and conduction through the IHS) TRs are eliminated, and boiling starts quickly at low power levels. The system's overall TR (including the die, the TIMs, the IHS, liquid-to-condenser, and condenser-to-air thermal resistances) did not show any significant changes from low to high power for the coated die.

A possible variant to the application of the MuSEP coating on the die is to apply the coating such that it extends beyond the boundaries of the die and thus provide a larger boiling surface. This could be accomplished by using an IHS with an aperture that exposes the die, allowing making the electrodeposition such that the coating is deposited on the die surface (via one or more intermediate layers) and at the same time the coating is also deposited on portions the IHS surrounding the die. In this fashion a larger boiling surface is achieved while retaining the advantage of having the coating deposited on the die.

### EXAMPLES

The following examples describe some exemplary modes of making and practicing certain compositions that are described herein. These examples are for illustrative purposes only and are not meant to limit the scope of the compositions and methods described herein.

### Example 1: Multi-Step Electroplating

In this non-limiting example, a coating in accordance with an embodiment is deposited through electroplating on a heat transfer surface of a data processor.

A primary solution containing sulfuric acid, copper sulfate, additive, and brightener was used for electroplating (Elevate Cu D6370, Technic Inc, USA). The substrate was contacted with the primary solution and electroplating was performed to obtain the porous coating having the desired characteristics. Notably, by controlling current density and plating duration, the resulting coating was characterized with having a plurality of metal-based grains defining pores, where the pores form more than 35% of void area.

While the following electroplating process is shown as including multiple steps, the reader will readily understand that other variations having more or less steps may be used to obtain the desired coating.

A first electroplating step was performed to obtain an anchor porous layer on the substrate layer, where there was proper adhesion made between the anchor porous layer and the substrate layer underneath the porous layer. A low current density (about 30 mA/cm²) for 5 min was applied at this step.

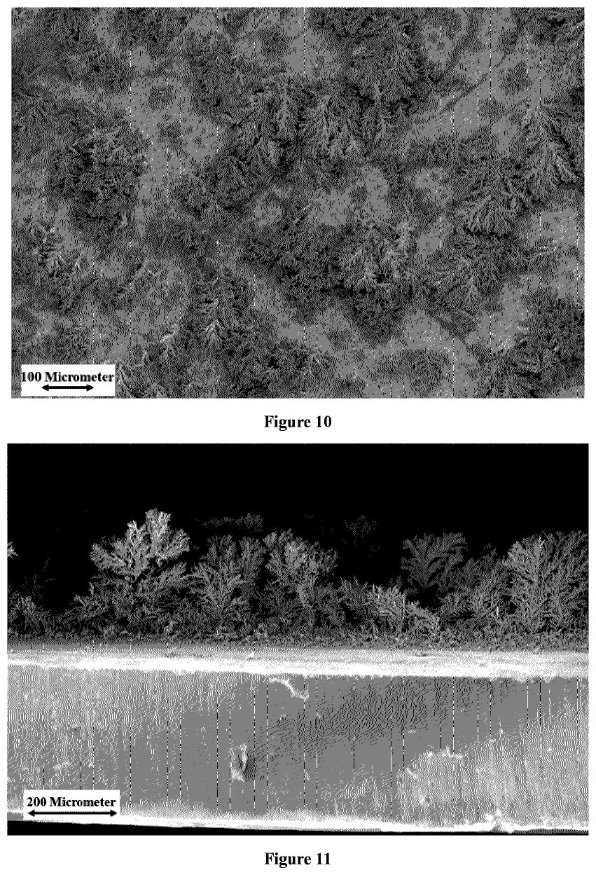

A second electroplating step was performed to obtain a highly porous layer that provides enough active sites for grains nucleation. A high current density (500-600 mA/cm²) for 10 s was applied at this step. FIG. 10 and FIG. 11 are scanning electron microscope (SEM) images of the layers obtained after this step, showing dendrite-shape structures, which collectively form a porous structure on top of the substrate.

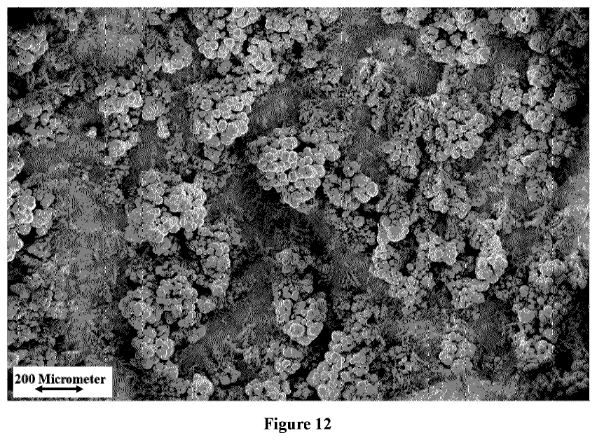

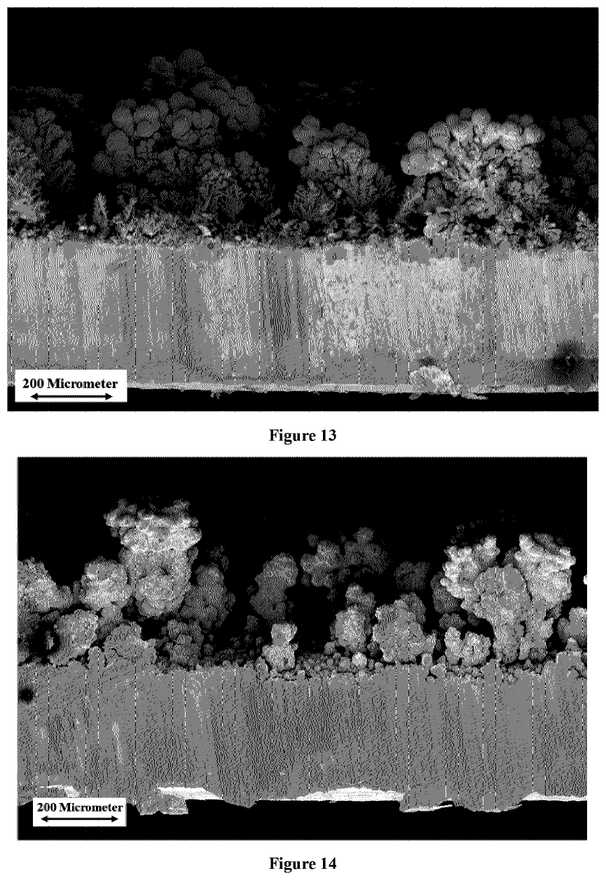

A third electroplating step was performed to further form grains on top of the previous porous structure. A medium current density (150 mA/cm²) for 10 min was applied at this step. The second porous layer completely disappeared at this step, and a new porous structure was formed. FIG. 12 and FIG. 13 are SEM images of the layers obtained after this step, showing the dendrite-shape structures from the second electroplating as exhibiting a certain degree of growth and fortification.

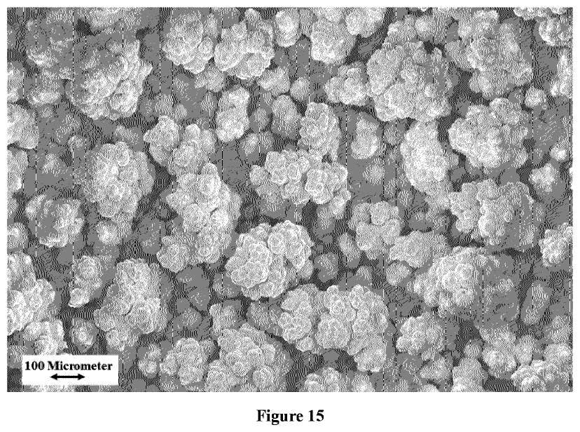

A fourth electroplating step was performed to rigidify the resulting porous coating structure. A low current density (30 mA/cm²) for 3-5 hours was applied at this step. FIG. 14 and FIG. 15 are SEM images of the coating obtained after this step.

Optionally, the data processor with the coating can be washed with suitable washing solutions (e.g., distilled water) to remove residues and dried.

Other examples of implementations will become apparent to the reader in view of the teachings of the present description and as such, will not be further described here.

Note that titles or subtitles may be used throughout the present disclosure for convenience of a reader, but in no way these should limit the scope of the invention. Moreover, certain theories may be proposed and disclosed herein; however, in no way they, whether they are right or wrong, should limit the scope of the invention so long as the invention is practiced according to the present disclosure without regard for any particular theory or scheme of action.

All references cited throughout the specification are hereby incorporated by reference in their entirety for all purposes.

Reference throughout the specification to “some embodiments”, and so forth, means that a particular element (e.g., feature, structure, and/or characteristic) described in connection with the invention is included in at least one embodiment described herein, and may or may not be present in other embodiments. In addition, it is to be understood that the described inventive features may be combined in any suitable manner in the various embodiments.

It will be understood by those of skill in the art that throughout the present specification, the term “a” used before a term encompasses embodiments containing one or more to what the term refers. It will also be understood by those of skill in the art that throughout the present specification, the term “comprising”, which is synonymous with “including,” “containing,” or “characterized by,” is inclusive or open-ended and does not exclude additional, un-recited elements or method steps.

Unless otherwise defined, all technical and scientific terms used herein have the same meaning as commonly understood by one of ordinary skill in the art to which this invention pertains. In the case of conflict, the present document, including definitions will control.

As used in the present disclosure, the terms “around”, “about” or “approximately” shall generally mean within the error margin generally accepted in the art. Hence, numerical quantities given herein generally include such error margin such that the terms “around”, “about” or “approximately” can be inferred if not expressly stated.

Although various embodiments of the disclosure have been described and illustrated, it will be apparent to those skilled in the art considering the present description that numerous modifications and variations can be made. The scope of the invention is defined more particularly in the appended claims

### K. REFERENCES

[1] X. Chen, H. Ye, X. Fan, T. Ren, and G. Zhang, “A review of small heat pipes for electronics,” Appl. Therm. Eng., vol. 96, pp. 1-17, March 2016, doi: 10.1016/j.applthermaleng.2015.11.048.
[2] K. Baraya, J. A. Weibel, and S. V. Garimella, “Heat pipe dryout and temperature hysteresis in response to transient heat pulses exceeding the capillary limit,” Int. J. Heat Mass Transf., vol. 148, p. 119135, February 2020, doi: 10.1016/j.ijheatmasstransfer.2019.119135.
[3] C.-C. Chen and L. Milor, “System-Level Modeling and Microprocessor Reliability Analysis for Backend Wearout Mechanisms,” in Design, Automation & Test in Europe Conference & Exhibition (DATE), 2013, Grenoble, France, 2013, pp. 1615-1620. doi: 10.7873/DATE.2013.328.
[4] A. Nazari and S. Saedodin, “Porous anodic alumina coating for optimisation of pool-boiling performance,” Surf. Eng., vol. 33, no. 10, pp. 753-759, October 2017, doi: 10.1080/02670844.2016.1199187.
[5] M. Može, M. Zupančič, and I. Golobič, “Pattern geometry optimization on superbiphilic aluminum surfaces for enhanced pool boiling heat transfer,” Int. J. Heat Mass Transf., vol. 161, p. 120265, November 2020, doi: 10.1016/j.ijheatmasstransfer.2020.120265.
[6] A. Heidary, H. Moghadasi, and H. Saffari, “Impact of dimensional characteristics of low-conductive channels on the enhancement of pool boiling: An experimental analysis,” Int. J. Mech. Sci., vol. 209, p. 106710, November 2021, doi: 10.1016/j.ijmecsci.2021.106710.
[7] O. Ghaffari, F. Grenier, J.-F. Morissette, M. Bolduc, S. Jasmin, and J. Sylvestre, “Pool Boiling Experiment of Dielectric Liquids and Numerical Study for Cooling a Microprocessor,” in 2019 18th IEEE Intersociety Conference on Thermal and Thermomechanical Phenomena in Electronic Systems (ITherm), Las Vegas, NV, USA, May 2019, pp. 540-545. doi: 10.1109/ITHERM.2019.8757380.
[8] G. Liang and I. Mudawar, “Review of pool boiling enhancement by surface modification,” Int. J. Heat Mass Transf., vol. 128, pp. 892-933, January 2019, doi: 10.1016/j.ijheatmasstransfer.2018.09.026.
[9] S. Swain, A. Swain, and S. P. Kar, “Influence of different surface coatings on pool boiling heat transfer enhancement: A brief review,” Mater. Today Proc., vol. 26, pp. 1903-1907, 2020, doi: 10.1016/j.matpr.2020.02.417.
[10] J. P. McHale, S. V. Garimella, T. S. Fisher, and G. A. Powell, “Pool Boiling Performance Comparison of Smooth and Sintered Copper Surfaces with and Without Carbon Nanotubes,” Nanoscale Microscale Thermophys. Eng., vol. 15, no. 3, pp. 133-150, July 2011, doi: 10.1080/15567265.2011.575918.
[11] C. A. Sayed et al., “Two-Phase Immersion Cooling of Microprocessors with Electroplated Porous Heat Spreaders: Thermal Performance and Reliability,” in 2021 20th IEEE Intersociety Conference on Thermal and Thermomechanical Phenomena in Electronic Systems (iTherm), San Diego, CA, USA, June 2021, pp. 410-416. doi: 10.1109/ITherm51669.2021.9503279.
[12] Y. Takata, S. Hidaka, M. Masuda, and T. Ito, “Pool boiling on a superhydrophilic surface,” Int. J. Energy Res., vol. 27, no. 2, pp. 111-119, February 2003, doi: 10.1002/er.861.
[13] Y.-Q. Wang, J.-L. Luo, Y. Heng, D.-C. Mo, and S.-S. Lyu, “Wettability modification to further enhance the pool boiling performance of the micro nano bi-porous copper surface structure,” Int. J. Heat Mass Transf., vol. 119, pp. 333-342, April 2018, doi: 10.1016/j.ijheatmasstransfer.2017.11.080.
[14] C. M. Patil, K. S. V. Santhanam, and S. G. Kandlikar, “Development of a two-step electrodeposition process for enhancing pool boiling,” Int. J. Heat Mass Transf., vol. 79, pp. 989-1001, December 2014, doi: 10.1016/j.ijheatmasstransfer.2014.08.062.
[15] M. S. El-Genk and A. F. Ali, “Enhanced nucleate boiling on copper micro-porous surfaces,” Int. J. Multiph. Flow, vol. 36, no. 10, pp. 780-792, October 2010, doi: 10.1016/j.ijmultiphaseflow.2010.06.003.
[16] K. C. Leong, J. Y. Ho, and K. K. Wong, “A critical review of pool and flow boiling heat transfer of dielectric fluids on enhanced surfaces,” Appl. Therm. Eng., vol. 112, pp. 999-1019, February 2017, doi: 10.1016/j.applthermaleng.2016.10.138.
[17] J. Gao, L.-S. Lu, J.-W. Sun, X.-K. Liu, and B. Tang, “Enhanced boiling performance of a nanoporous copper surface by electrodeposition and heat treatment,” Heat Mass Transf., vol. 53, no. 3, pp. 947-958, March 2017, doi: 10.1007/s00231-016-1868-4.
[18] A. Mehdikhani, H. Moghadasi, and H. Saffari, “An experimental investigation of pool boiling augmentation using four-step electrodeposited micro/nanostructured porous surface in distilled water,” Int. J. Mech. Sci., vol. 187, p. 105924, December 2020, doi: 10.1016/j.ijmecsci.2020.105924.
[19] 3M™ Novec™ Engineered Fluid, 649, “3M Science. Applied to Life™.” [Online]. Available: https://www.3mcanada.ca/3M/en_CA/p/d/b5005005025/
[20] O. Ghaffari et al., “Experimental Investigation of the Effect of Heat Spreading on Boiling of a Dielectric Liquid for Immersion Cooling of Electronics,” J. Electron. Packag., vol. 143, no. 4, p. 041103, December 2021, doi: 10.1115/1.4051943.
[21] J. Sylvestre, “APPARATUS AND METHODS FOR COOLING OF AN INTEGRATED CIRCUIT,” U.S. Pat. No. 10,390,460B2
[22] O. Ghaffari et al., “Two-Phase Closed-Loop Thermosyphon Filled with a Dielectric Liquid for Electronics Cooling Applications,” in 2021 20th IEEE Intersociety Conference on Thermal and Thermomechanical Phenomena in Electronic Systems (iTherm), San Diego, CA, USA, June 2021, pp. 74-80. doi: 10.1109/ITherm51669.2021.9503149.
[23] Wayne Rasband, ImageJ. National Institutes of Health and the Laboratory for Optical and Computational Instrumentation. [Online]. Available: https://imagej.nih.gov/ij/
[24] I. Golobič and M. Zupančič, “Wall-temperature distributions of nucleate pool boiling surfaces vs. boiling curves: A new approach,” Int. J. Heat Mass Transf., vol. 99, pp. 541-547, August 2016, doi: 10.1016/j.ijheatmasstransfer.2016.04.033.
[25] Y.-Y. Li, Z.-H. Liu, and B.-C. Zheng, “Experimental study on the saturated pool boiling heat transfer on nano-scale modification surface,” Int. J. Heat Mass Transf., vol. 84, pp. 550-561, May 2015, doi: 10.1016/j.ijheatmasstransfer.2014.12.064.
[26] W. Zhou, X. Hu, L. Mao, and Y. He, “Markedly enhanced pool boiling heat transfer performance on maicropaorous copper surfaces fabricated utilizing a facile wire cutting process,” Appl. Therm. Eng., vol. 165, p. 114396, January 2020, doi: 10.1016/j.applthermaleng.2019.114396.
[27] C. Al Sayed et al., “Localized Pool Boiling and Condensation Experiments over Functional CPU: Optimizing the Overall Thermal Resistance via Different Heat Transfer Scenarios,” in 2020 19th IEEE Intersociety Conference on Thermal and Thermomechanical Phenomena in Electronic Systems (ITherm), Orlando, FL, USA, July 2020, pp. 410-416. doi: 10.1109/ITherm45881.2020.9190371.

What is claimed is:

1. A coating for use on a heat transport surface of a data processor, the coating comprising a plurality of metal-based grains defining pores, wherein the pores form more than 35% of void area, and wherein the coating is configured for immersion cooling of the data processor.

2. The coating according to claim 1, wherein the pores define a pore-size gradient along at least one dimension of the coating.

3. The coating according to claim 2, wherein the pore-size gradient extends along a thickness of the coating.

4. The coating according to claim 3, wherein the pore-size gradient includes increasingly larger pores in a direction of heat transport through the coating.

5. The coating according to claim 1, wherein the pores form more than 40% of void area, preferably more than 50% of void area, more preferably more than 60% of void area.

6. The coating according to claim 1, wherein the pores at a top surface of the coating have an average pore size of at least 100 microns, preferably of at least 150 microns, more preferably at least 200 microns.

7. The coating according to claim 1, wherein the plurality of grains form dendrite-like structures extending outwardly from a low surface thereof.

8. The coating according to claim 1, wherein the plurality of grains includes grains having a size of about 70 microns or more at a top surface thereof, preferably from about 70 microns to about 500 microns.

9. The coating according to claim 1, wherein the plurality of grains includes a plurality of first grains of first average size and a plurality of second grains of second average size above the plurality of grains of first average size, the second average size being larger than the first average size.

10. The coating according to claim 1, wherein the pores include a first plurality of pores having a concave shape and a second plurality of pores having a convex shape.

11. A coating for use on a heat transport surface of a data processor, the coating comprising a plurality of first grains of first average size and a plurality of second grains of second average size above the plurality of grains of first average size, the second average size being larger than the first average size, the plurality of grains of first average size defining pores configured to induce bubble nucleation, and the plurality of grains of second average size defining a liquid wicking structure to draw cooling liquid toward the pores, wherein the coating is configured for immersion cooling of the data processor.

12. (canceled)

13. A data processor comprising:
a) a semiconductor die on which a functional integrated semiconductor circuit is fabricated, the die having a surface, and
b) a porous coating deposited on the die for immersion cooling of the data processor.

14. The data processor according to claim 13, wherein the coating defines a physical protective layer for the semiconductor die.

15. The data processor according to claim 13, wherein the coating is bonded to the surface of the die through an intermediate layer.

16. The data processor according to claim 15, wherein the intermediate layer includes material configured to establish a bond with the material of the semiconductor die and the material of the coating.

17. The data processor according to claim 16, wherein the intermediate layer is a first intermediate layer, the data processor including a second intermediate layer between the first intermediate layer and the coating.

18. The data processor according to claim 13, wherein the coating includes a plurality of metal-based grains.

19. The data processor according to claim 18, wherein the plurality of metal-based grains include copper.

20. (canceled)

21. (canceled)
